(19) United States
(12) Patent Application Publication
(10) Pub. No.: US 2026/0047023 A1
(43) Pub. Date: Feb. 12, 2026

(54) DISPLAY DEVICE AND ELECTRONIC DEVICE INCLUDING THE SAME

(71) Applicant: Samsung Display Co., Ltd., Yongin-si (KR)

(72) Inventors: Yong Kwon SOH, Yongin-si (KR); Myung Sun KIM, Yongin-si (KR); Hun Tae KIM, Yongin-si (KR)

(21) Appl. No.: 19/196,328

(22) Filed: May 1, 2025

(30) Foreign Application Priority Data
Aug. 7, 2024 (KR) 10-2024-0105514

(51) Int. Cl. H05K 5/03

(52) U.S. Cl. CPC H05K 5/03

(57) ABSTRACT

A display device includes a display panel, a driver circuit on a surface of the display panel, a cover member over the surface of the display panel and the driver circuit, and a waterproof member on a surface of the cover member, wherein at least a part of the waterproof member is embedded in the cover member.

### CROSS-REFERENCE TO RELATED APPLICATION

The present application claims priority to and the benefit of Korean Patent Application No. 10-2024-0105514, filed on Aug. 7, 2024, in the Korean Intellectual Property Office, the entire disclosure of which is incorporated by reference herein.

### BACKGROUND

### 1. Field

The present disclosure relates to a display device and an electronic device including the same.

### 2. Description of the Related Art

Typically, electronic devices such as a smart phone, a tablet PC, a digital camera, a laptop computer, a navigation device and a smart TV include an organic light-emitting display device for displaying images.

Organic light-emitting display devices generally have good luminance, low driving voltage, fast response speed and a wide range of color reproduction, and accordingly are being employed by a variety of devices including smart phones. An organic light-emitting display device includes a display panel including organic light-emitting elements. In an organic light-emitting element, a cathode electrode and an anode electrode are disposed around an organic emissive layer. When a voltage is applied to the cathode electrode and the anode electrode, visible light is generated in the organic emissive layer connected to the two electrodes.

Organic light-emitting display devices are widely used in portable electronic devices such as smartphones. Because an organic light-emitting layer is vulnerable to moisture, there is a risk that an organic light-emitting display device may be damaged by liquid and/or the like introduced from the outside. In order to protect an organic light-emitting display device from liquid introduced from the outside, the organic light-emitting display may include a waterproof member.

### SUMMARY

Aspects and features of embodiments of the present disclosure provide a display device that can prevent a waterproof member from being attached incorrectly and from deviating by liquid introduced from the outside, and an electronic device including the display device.

However, aspects and features of embodiments of the present disclosure are not restricted to those set forth herein. The above and other aspects of the present disclosure will become more apparent to one of ordinary skill in the art to which the present disclosure pertains by referencing the detailed description of the present disclosure given below.

According to one or more embodiments of the present disclosure, a display device includes a display panel, a driver circuit on a surface of the display panel, a cover member over the surface of the display panel and the driver circuit, and a waterproof member on a surface of the cover member, wherein at least a part of the waterproof member is embedded in the cover member.

In one or more embodiments, the cover member further includes a guide portion that is recessed from the surface of the cover member in a thickness direction of the cover member, and wherein a part of the waterproof member is inside the guide portion.

In one or more embodiments, the cover member includes a first cover sheet on the surface of the display panel and a second cover sheet on a surface of the first cover sheet.

In one or more embodiments, the guide portion is recessed from a surface of the second cover sheet in a thickness direction of the second cover sheet.

In one or more embodiments, the guide portion is an area where a part of the second cover sheet is removed so that a part of the surface of the first cover sheet is exposed to the outside, and wherein the waterproof member is in contact with the surface of the first cover sheet that is exposed to the outside.

In one or more embodiments, the guide portion is extended in a first direction and a second direction, and wherein an extension length of the guide portion in the first direction is larger than an extension length of the guide portion in the second direction.

In one or more embodiments, the guide portion is extended from one end of the cover member in the first direction to an opposite end in the first direction.

In one or more embodiments, the waterproof member is in contact with an end of the guide portion in the first direction and is spaced from an end of the guide portion in the second direction.

In one or more embodiments, the first cover sheet and the second cover sheet include different materials.

In one or more embodiments, the cover member further includes a third cover sheet between the surface of the display panel and the first cover sheet.

In one or more embodiments, the third cover sheet includes a material different from at least one of the first cover sheet or the second cover sheet.

In one or more embodiments, a thickness of the second cover sheet is larger than a thickness of at least one of the first cover sheet or the third cover sheet.

In one or more embodiments, a thickness of the third cover sheet is equal to a thickness of the first cover sheet.

In one or more embodiments, a thickness of the waterproof member is larger than a thickness of the second cover sheet.

In one or more embodiments, the thickness of the waterproof material is equal to or less than twice the thickness of the second cover sheet.

In one or more embodiments, the display device further includes a flexible film on an edge of the display panel, wherein the guide portion is between the driver circuit and the flexible film.

According to one or more embodiments of the present disclosure, a display device includes a display panel, a driver circuit on a surface of the display panel, a first cover sheet over the surface of the display panel and the driver circuit, a second cover sheet on a surface of the first cover sheet, a guide portion formed by removing a part of the second cover sheet so that a part of the surface of the first cover sheet is exposed to an outside, and a waterproof member in the guide portion and in contact with the surface of the first cover sheet exposed to the outside.

In one or more embodiments, the guide portion is extended in a first direction and a second direction, and wherein an extension length of the guide portion in the first direction is larger than an extension length of the guide portion in the second direction.

In one or more embodiments, the guide portion is extended from one end of the first cover sheet in the first direction to an opposite end in the first direction.

In one or more embodiments, the waterproof member is in contact with an end of the guide portion in the first direction and is spaced from an end of the guide portion in the second direction.

In one or more embodiments, a thickness of the waterproof member is larger than a thickness of the second cover sheet.

In one or more embodiments, the display device further includes a flexible film on an edge of the display panel, wherein the guide portion is between the driver circuit and the flexible film.

According to one or more embodiments of the present disclosure, an electronic device includes a display panel, a driver circuit on a surface of the display panel, a cover member over the surface of the display panel and the driver circuit, and a waterproof member on a surface of the cover member, wherein at least a part of the waterproof member is embedded in the cover member.

In one or more embodiments, the cover member further includes a guide portion that is recessed from the surface of the cover member in a thickness direction of the cover member, and wherein a part of the waterproof member is inside the guide portion.

In one or more embodiments, the cover member includes a first cover sheet on the surface of the display panel, and a second cover sheet on a surface of the first cover sheet.

In one or more embodiments, the guide portion is recessed from a surface of the second cover sheet in a thickness direction of the second cover sheet.

In one or more embodiments, the guide portion is an area where a part of the second cover sheet is removed so that a part of the surface of the first cover sheet is exposed to the outside, and wherein the waterproof member is in contact with the surface of the first cover sheet that is exposed to the outside.

In one or more embodiments, the guide portion is extended in a first direction and a second direction, and wherein an extension length of the guide portion in the first direction is larger than an extension length of the guide portion in the second direction.

In one or more embodiments, the guide portion is extended from one end of the cover member in the first direction to an opposite end in the first direction.

In one or more embodiments, the waterproof member is in contact with an end of the guide portion in the first direction and is spaced from an end of the guide portion in the second direction.

In one or more embodiments, the first cover sheet and the second cover sheet include different materials.

In one or more embodiments, the cover member further includes a third cover sheet between the surface of the display panel and the first cover sheet.

In one or more embodiments, the third cover sheet comprises a material different from at least one of the first cover sheet or the second cover sheet.

In one or more embodiments, a thickness of the second cover sheet is larger than a thickness of at least one of the first cover sheet or the third cover sheet.

In one or more embodiments, a thickness of the third cover sheet is equal to a thickness of the first cover sheet.

In one or more embodiments, a thickness of the waterproof member is larger than a thickness of the second cover sheet.

In one or more embodiments, the thickness of the waterproof material is equal to or less than twice the thickness of the second cover sheet.

In one or more embodiments, the electronic device further includes a flexible film on an edge of the display panel, wherein the guide portion is between the driver circuit and the flexible film.

According to one or more embodiments of the present disclosure, it is possible to prevent a waterproof member in a display device from being attached incorrectly and from deviating by liquid introduced from the outside.

The effects, aspects, and features of embodiments of the present disclosure are not limited to those mentioned above and more various effects, aspects, and features are included in the following description of the present disclosure.

### BRIEF DESCRIPTION OF THE DRAWINGS

The above and other aspects and features of the present disclosure will become more apparent by describing in detail example embodiments thereof with reference to the attached drawings, in which:

FIG. 1 is a plan view of an electronic device according to one or more embodiments of the present disclosure.

FIG. 2 is a plan view showing a display device according to one or more embodiments of the present disclosure when a flexible film of the display device is unfolded.

FIG. 3 is a view showing the display device of FIG. 2 in which a guide portion is extended from one side to the opposite side of a cover member in the first direction.

FIG. 4 is a plan view of the display device of FIG. 2 when the cover member and the waterproof member are removed.

FIG. 5 is a bottom view showing the display device according to one or more embodiments of the present disclosure when a flexible film is bent.

FIG. 6 is a view showing the display device of FIG. 5 in which a guide portion is extended from one side to the opposite side of a cover member in the first direction.

FIG. 7 is a cross-sectional view taken along the line A-A′ of FIG. 5.

FIG. 8 is an enlarged view of a portion B of FIG. 5.

FIG. 9 is a view showing the portion of FIG. 8 after the waterproof member has been removed.

FIG. 10 is an enlarged view of the portion B of FIG. 6.

FIG. 11 is a view showing the portion of FIG. 10 after the waterproof member has been removed.

FIG. 12 is a cross-sectional view showing a cover member of a display device according to one or more embodiments of the present disclosure.

FIG. 13 is an enlarged view of a portion C of FIG. 7.

FIG. 14 is a view showing the portion of FIG. 13 after the waterproof member has been removed.

FIG. 15 is a view showing the portion of FIG. 13 where waterproof glue is provided as the waterproof member.

FIG. 16 is a view showing the portion of FIG. 13 when liquid is introduced from the outside.

FIG. 17 is a view showing the portion of FIG. 15 when liquid is introduced from the outside.

### DETAILED DESCRIPTION

Aspects and features of the present disclosure and methods to achieve them will become apparent from the descriptions of example embodiments hereinbelow with reference to the accompanying drawings. However, the present disclosure is not limited to example embodiments disclosed herein but may be implemented in various different ways. The example embodiments are provided for making the present disclosure thorough and for fully conveying the scope of the present disclosure to those skilled in the art. It is to be noted that the scope of the present disclosure may be defined by the claims and their equivalents.

As used herein, a phrase “an element A on an element B” refers to that the element A may be disposed directly on the element B and/or the element A may be disposed indirectly on the element B via another element C. Like reference numerals denote like elements throughout the present disclosure. The figures, dimensions, ratios, angles, numbers of elements given in the drawings are merely illustrative and are not limiting.

Although terms such as first, second, etc. are used to distinguish arbitrarily between the elements such terms describe, and thus these terms are not necessarily intended to indicate temporal or other prioritization of such elements.

These terms are used to merely distinguish one element from another. Accordingly, as used herein, a first element may be a second element within the technical scope of the present disclosure.

Features of various example embodiments of the present disclosure may be combined partially or totally. As will be clearly appreciated by those skilled in the art, technically various interactions and operations are possible. Various example embodiments can be practiced individually or in combination.

For the purposes of the present disclosure, expressions such as “at least one of,” “one of,” and “selected from,” when preceding a list of elements, modify the entire list of elements and do not modify the individual elements of the list. For example, “at least one of X, Y, and Z,” “at least one of X, Y, or Z,” and “at least one selected from the group consisting of X, Y, and Z” may be construed as X only, Y only, Z only, any combination of two or more of X, Y, and Z, such as, for instance, XYZ, XYY, XZ, YZ, and ZZ, or any variation thereof. Similarly, the expression such as “at least one of A and/or B” may include A, B, or A and B. As used herein, the term “and/or” includes any and all combinations of one or more of the associated listed items. For example, the expression such as “A and/or B” may include A, B, or A and B. Further, the use of “may” when describing embodiments of the present disclosure refers to “one or more embodiments of the present disclosure”.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Hereinafter, example embodiments of the present disclosure will be described in detail with reference to the accompanying drawings.

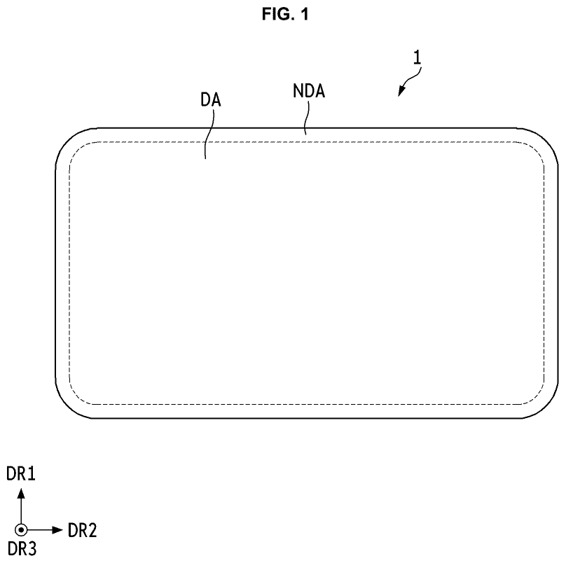

FIG. 1 is a plan view of an electronic device 1 including a display device 10 according to one or more embodiments of the present disclosure.

Referring to FIG. 1, the electronic device 1 according to one or more embodiments of the present disclosure may include a variety of electronic devices that provide a display screen. Examples of the electronic device 1 may include, but are not limited to, a mobile phone, a smart phone, a tablet PC, a mobile communications terminal, an electronic organizer, an e-book, a personal digital assistant (PDA), a portable multimedia player (PMP), a navigation device, an ultra-mobile PC (UMPC), a television set, a game machine, a wristwatch-type electronic device, a head-mounted display, a personal computer monitor, a laptop computer, a vehicle instrument cluster, a digital camera, a camcorder, an outdoor billboard, an electronic billboard, various medical apparatuses, various inspection devices, various home appliances including a display area such as a refrigerator and a laundry machine, Internet of things (IoT) devices, etc. Examples of the electronic device 1 may include, but are not limited to, a smartphone, a tablet PC, a laptop computer, etc.

The electronic device 1 may include a display area DA and a non-display area NDA along an edge or a periphery of the display area DA. The shape of the display area DA may follow the shape of the electronic device 1 when viewed from the top. For example, when the electronic device 1 has a rectangular shape when viewed from the top, the display area DA may also have a rectangular shape when viewed from the top.

The display area DA may include a plurality of pixels of the display device 10 to display images. The non-display area NDA may display no image because it does not include the pixels of the display device 10. The non-display area NDA may be disposed around the display area DA. The non-display area NDA may surround the display area DA, but the present disclosure is not limited thereto. The display area DA may be partially surrounded by the non-display area NDA.

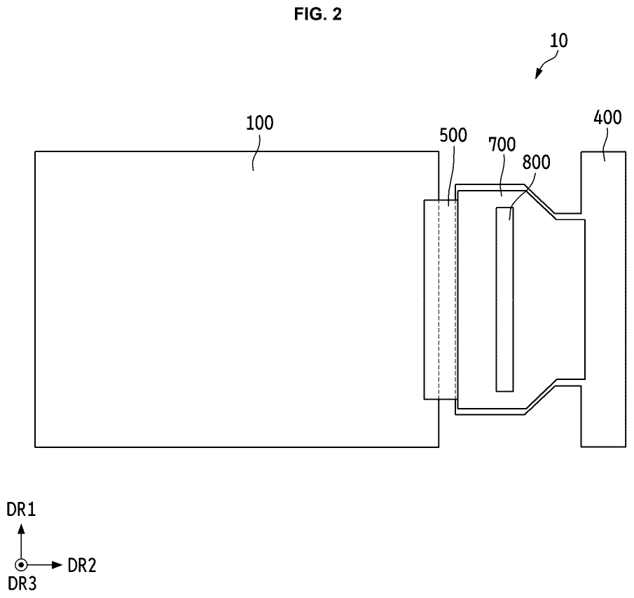

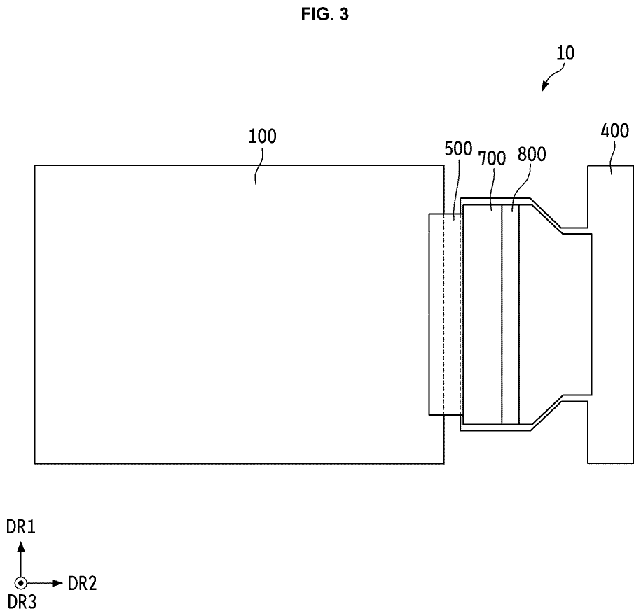

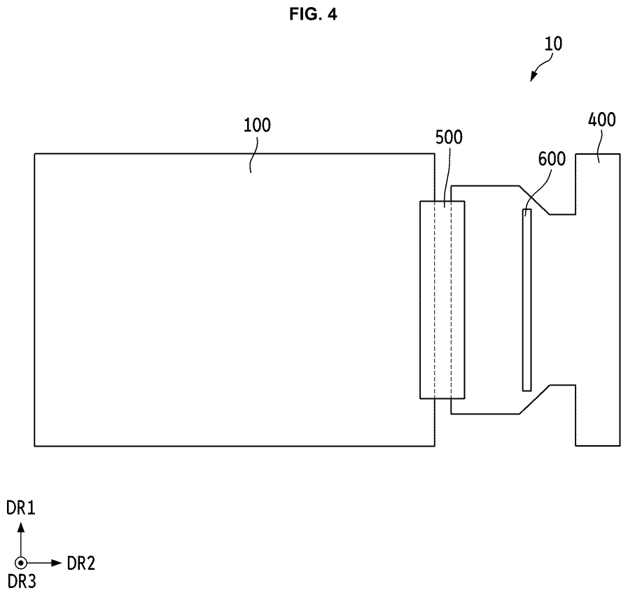

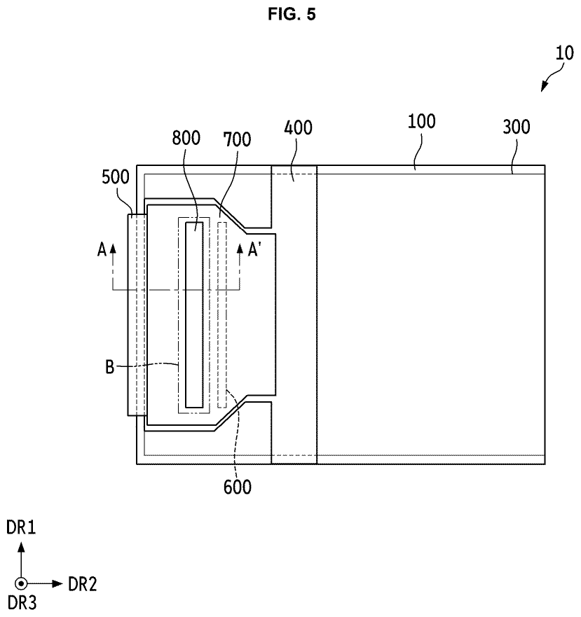

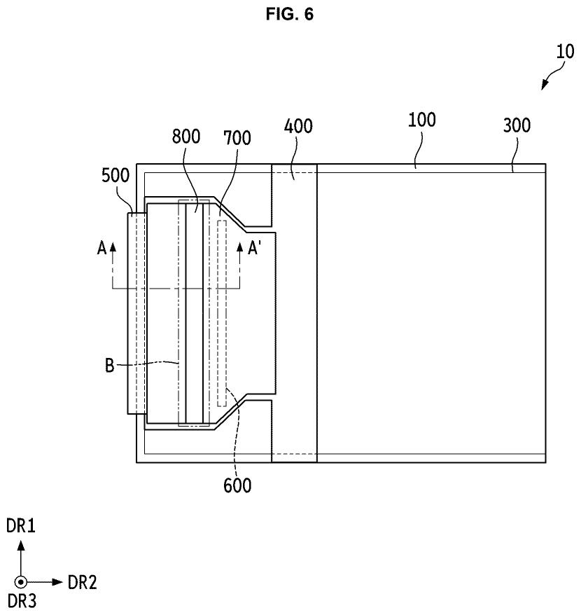

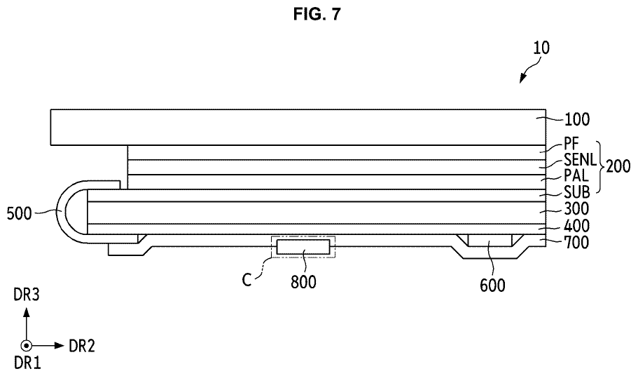

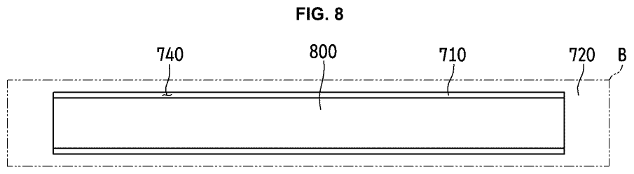

FIG. 2 is a plan view showing the display device 10 when a flexible film 500 of the display device 10 is unfolded according to one or more embodiments of the present disclosure. FIG. 3 is a view showing the display device of FIG. 2 in which a guide portion 740 (e.g., see FIG. 8) is extended from one side to the opposite side of a cover member 700 in the first direction DR1. FIG. 4 is a plan view showing the display device 10 of FIG. 2 when the cover member 700 and the waterproof member 800 are removed. FIG. 5 is a bottom view showing the display device 10 according to one or more embodiments of the present disclosure when a flexible film 500 is bent. FIG. 6 is a view showing the display device of FIG. 5 in which the guide portion 740 is extended from one side to the opposite side of the cover member 700 in the first direction DR1. FIG. 7 is a cross-sectional view taken along the line A-A′ of FIG. 5.

The electronic device 1 according to this embodiment may include the display device 10. The display device 10 is for displaying moving images and/or still images. The display device 10 may be used as the display screen of portable electronic devices such as a mobile phone, a smart phone, a tablet PC, a smart watch, a watch phone, a mobile communications terminal, an electronic notebook, an electronic book, a portable multimedia player (PMP), a navigation device and a ultra mobile PC (UMPC), as well as the display screen of various products such as a television, a notebook, a monitor, a billboard, and/or the Internet of Things (IoTs). Alternatively, the display device 10 may be used as a display screen applied to the center fascia of a vehicle. In the following description, the display device 10 according to one or more embodiments of the present disclosure is a smartphone. It is, however, to be understood that the present disclosure is not limited thereto.

The display device 10 may be a light-emitting display device such as an organic light-emitting display device using organic light-emitting diodes (OLEDs), a quantum-dot light-emitting display device including quantum-dot light-emitting layer, an inorganic light-emitting display device including an inorganic semiconductor, and a micro light-emitting display device using micro light-emitting diodes (LED). In the following description, an organic light-emitting display device is described as an example of the display device 10. It is, however, to be understood that the present disclosure is not limited thereto.

Referring to FIGS. 2-7, the display device 10 according to one or more embodiments of the present disclosure may include a cover window 100, a display panel 200, a panel bottom member 300, a circuit board 400, a flexible film 500, a driver circuit 600, a cover member 700, and a waterproof member 800.

As used herein, a first direction DR1 may be parallel to the shorter sides of the display device 10, for example, the vertical direction of the display device 10. A second direction DR2 may be parallel to the longer sides of the display device 10, for example, the horizontal direction of the display device 10 when viewed from the top. A third direction DR3 may refer to the thickness direction of the display device 10. The upper portion may refer to the side indicated by the arrow of the third direction DR3, while the lower portion may refer to the opposite side in the third direction DR3.

The display device 10 may have a rectangular shape when viewed from the top. For example, the display device 10 may have a shape similar to a rectangle having shorter sides in the first direction DR1 and longer sides in the second direction DR2 when viewed from the top. The corners where the shorter sides in the first direction DR1 meet the longer sides in the second direction DR2 may be rounded with a suitable curvature (e.g., a predetermined curvature) or may be a right angle. The shape of the display device 10 when viewed from the top is not limited to a rectangular shape but may be formed in another polygonal shape, a circular shape, or an elliptical shape.

The cover window 100 may be disposed on the display panel 200 to cover the upper surface of the display panel 200. The cover window 100 can protect the upper surface of the display panel 200. The cover window 100 may include a light-transmitting portion and a light-blocking portion.

The cover window 100 may include a material with high light transmittance. The cover window 100 may include a polymer resin such as polyimide and/or glass. The cover window 100 may be attached onto a polarizing film PF of the display panel 200 by an adhesive member such as an optically clear adhesive (OCA) film.

The display panel 200 may be disposed under the cover window 100. The display panel 200 may have a rectangular shape having shorter sides in the first direction DR1 and longer sides in the second direction DR2 when viewed from the top. In the display panel 200, the corners where the shorter sides in the first direction DR1 meet the longer sides in the second direction DR2 may be a right angle or may be rounded with a suitable curvature (e.g., a predetermined curvature). The display panel 200 may have a quadrangular shape other than a rectangle, a polygonal shape other than a quadrangular shape, a circular shape, an oval shape, or an irregular shape when viewed from the top.

The display panel 200 may include a display area where a plurality of emission areas that emits light is arranged, and a non-display area disposed around the display area. The non-display area may surround the display area. A plurality of display pads may be disposed in the non-display area at at least one edge of the display panel 200.

The display panel 200 may include a substrate SUB, a display unit PAL, a sensor unit SENL and a polarizing film PF.

The substrate SUB may be made of an insulating material such as glass, quartz, and/or a polymer resin. The substrate SUB may be a rigid substrate or a flexible substrate that can be bent, folded, rolled, and so on.

The display unit PAL may be disposed on the substrate SUB. The display unit PAL may be a layer including a plurality of emission areas that emit light. The display unit PAL may include a buffer film, a thin-film transistor layer on which thin-film transistors are disposed, a light-emitting element layer that is configured to emit light, and an encapsulating layer for encapsulating the light-emitting element layer.

The sensor unit SENL may be disposed on the display unit PAL. The sensor unit SENL may include sensor electrodes and may sense whether there is a user's touch.

The polarizing film PF may be disposed on the sensor unit SENL. The polarizing film PF can prevent or reduce the deterioration of image visibility of the display panel 200 due to reflection of external light. The polarizing film may include a linear polarizer and/or a retardation film such as a λ/4 (quarter-wave) plate. The phase retardation film may be disposed on the sensor unit SENL, and the linear polarizer may be disposed on the phase retardation film. The cover window 100 may be disposed on the polarizing film PF.

The panel bottom member 300 may be disposed under the substrate SUB. The panel bottom member 300 may be attached to the lower surface of the substrate SUB by an adhesive member. The adhesive member may be a pressure-sensitive adhesive (PSA). The panel bottom member 300 may include: a light-absorbing member for absorbing light incident from outside, a buffer member for absorbing external impact, and/or a heat dissipating member for efficiently discharging heat from the display panel 200.

The light-absorbing member may be disposed under the substrate SUB. The light-absorbing member blocks the transmission of light to prevent the elements disposed thereunder from being seen from above the display panel 200, such as the circuit board 400. The light-absorbing member may include a light-absorbing material such as a black pigment and/or a black dye.

The buffer member may be disposed under the light-absorbing member. The buffer member absorbs an external impact to prevent the display panel 200 from being damaged. The buffer member may include a single layer or multiple layers. For example, the buffer member may be formed of a polymer resin such as polyurethane, polycarbonate, polypropylene, and/or polyethylene, and/or may be formed of a material having elasticity such as a rubber and a sponge obtained by foaming a urethane-based material and/or an acrylic-based material.

The heat dissipating member may be disposed under the buffer member. The heat dissipation member may include a first heat dissipation layer including graphite and/or carbon nanotubes, and a second heat dissipation layer formed of a thin metal film such as copper, nickel, ferrite, and/or silver, which can block electromagnetic waves and have high thermal conductivity.

The circuit board 400 may be disposed under the panel bottom member 300. The circuit board 400 may be a flexible printed circuit board (FPCB) that can be bent, a rigid printed circuit board (PCB) that is rigid and not bendable, or a hybrid printed circuit board (PCB) including a rigid printed circuit board (PCB) and a flexible printed circuit board (FPCB).

The flexible film 500 may be connected to a plurality of display pads of the display panel 200 through a conductive adhesive member such as an anisotropic conductive film. In this manner, the display panel 200 can be electrically connected with the flexible film 500.

In addition, the flexible film 500 may be connected to a plurality of circuit pads of the circuit board 400 through a conductive adhesive material such as an anisotropic conductive film. In this manner, the flexible film 500 may be electrically connected to the circuit board 400.

The flexible film 500 may be a flexible printed circuit board (FPCB) or a chip-on-film (CoF).

The driver circuit 600 receives control signals and power voltages through the circuit board 400, and generates and outputs signals and voltages for driving the display panel 200. The driver circuit 600 may be implemented as, but is not limited to, an integrated circuit (IC) and may be attached to the circuit board 400.

The cover member 700 may be disposed on a surface of the display panel 200 to cover a surface of the display panel 200 and the driver circuit 600. The cover member 700 may be disposed on a surface of the circuit board 400 disposed on the surface of the display panel 200. The cover member 700 can protect the circuit board 400 and the driver circuit 600 from external shock. The surface of the display panel 200 may be the lower surface of the display panel 200 in FIG. 7, and the surface of the circuit board 400 may be the lower surface of the circuit board 400 in FIG. 7.

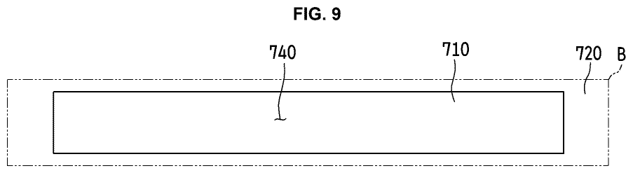

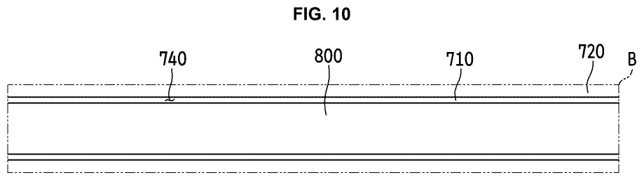

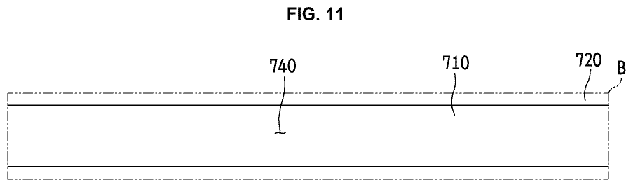

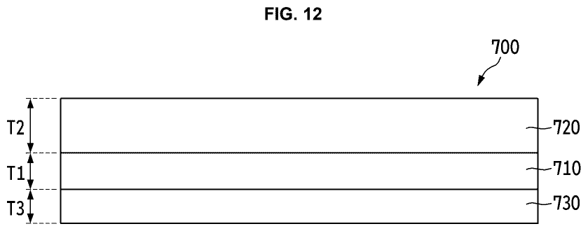

FIG. 8 is an enlarged view of a portion B of FIG. 5. FIG. 9 is a view showing the portion of FIG. 8 after the waterproof member 800 has been removed. FIG. 10 is an enlarged view of the portion B of FIG. 6. FIG. 11 is a view showing the portion of FIG. 10 after the waterproof member 800 has been removed. FIG. 12 is a cross-sectional view showing the cover member 700 of the display device 10 according to one or more embodiments of the present disclosure.

Referring further to FIGS. 8-12, the cover member 700 may include a first cover sheet 710, a second cover sheet 720, a third cover sheet 730, and a guide portion 740.

The first cover sheet 710 may be disposed on the surface of the circuit board 400. The first cover sheet 710 may be provided as a sheet having a suitable thickness (e.g., a predetermined thickness) T1. The first cover sheet 710 may be a metal sheet formed of a conductive material such as copper (Cu), and may also be a polymer resin sheet such as polyethylene terephthalate and/or polyimide.

The first cover sheet 710 may be disposed to entirely cover the surface of the display panel 200. In one or more embodiments, the first cover sheet 710 may be disposed to entirely cover the surface of the circuit board 400 disposed on the surface of the display panel 200. An adhesive layer may be disposed on the opposite surface of the first cover sheet 710, so that the opposite surface of the first cover sheet 710 may be adhered to the surface of the third cover sheet 730 disposed between the first cover sheet 710 and the surface of the circuit board 400. The surface of the first cover sheet 710 may be the upper surface of the first cover sheet 710 in FIG. 12, and the opposite surface of the first cover sheet 710 may be the lower surface of the first cover sheet 710 in FIG. 12.

The second cover sheet 720 may be disposed on the surface of the first cover sheet 710. The second cover sheet 720 may be provided as a sheet having a suitable thickness (e.g., a predetermined thickness) T2. The second cover sheet 720 may be formed of a different material from the first cover sheet 710. For example, when the first cover sheet 710 is provided as a metal sheet formed of a conductive material such as copper, the second cover sheet 720 may be provided as a polymer resin sheet such as polyethylene terephthalate and/or polyimide.

The second cover sheet 720 may be disposed to entirely cover the surface side of the first cover sheet 710. The thickness T2 of the second cover sheet 720 may be larger than the thickness T1 of the first cover sheet 710 and the thickness T3 of the third cover sheet 730. An adhesive layer may be disposed on the opposite surface of the second cover sheet 720 so that the opposite surface of the second cover sheet 720 may be adhered to the surface of the first cover sheet 710. The surface of the second cover sheet 720 may be the upper surface of the second cover sheet 720 in FIG. 12, and the opposite surface of the second cover sheet 720 may be the lower surface of the second cover sheet 720 in FIG. 12.

The third cover sheet 730 may be disposed between the surface of the circuit board 400 and the opposite surface of the first cover sheet 710. The third cover sheet 730 may be provided as a sheet having a suitable thickness (e.g., a predetermined thickness) T3. The third cover sheet 730 may be formed of a different material from at least one of the first cover sheet 710 or the second cover sheet 720. For example, when the first cover sheet 710 is provided as a metal sheet formed of a conductive material such as copper, the third cover sheet 730 may be provided as a polymer resin sheet such as polyethylene terephthalate and polyimide.

The third cover sheet 730 may be disposed to entirely cover the surface of the circuit board 400. The thickness T3 of the third cover sheet 730 may be smaller than the thickness T2 of the second cover sheet 720 and may be equal to the thickness T1 of the first cover sheet 710. An adhesive layer may be disposed on the opposite surface of the third cover sheet 730 so that the opposite surface of the third cover sheet 730 may be adhered to the surface of the circuit board 400. The surface of the third cover sheet 730 may be adhered to the opposite surface of the first cover sheet 710 by the adhesive layer disposed on the opposite surface of the first cover sheet 710. The surface of the third cover sheet 730 may be the upper surface of the third cover sheet 730 in FIG. 12, and the opposite surface of the third cover sheet 730 may be the lower surface of the third cover sheet 730 in FIG. 12.

The guide portion 740 may be formed such that it is recessed in the thickness direction of the second cover sheet 720 from the surface of the second cover sheet 720. The guide portion 740 may be formed by removing a part of the second cover sheet 720. For example, the guide portion 740 may be an area where a part of the second cover sheet 720 is removed so that the surface of the first cover sheet 710 is exposed to the outside.

The guide portion 740 may be extended in the first direction DR1 and the second direction DR2. The extension length of the guide portion 740 in the first direction DR1 may be larger than the extension length of the guide portion 740 in the second direction DR2. In one or more embodiments, the guide portion 740 may be a rectangular groove having longer sides in the first direction DR1 and shorter sides in the second direction DR2. The guide portion 740 may be located between the flexible film 500 and the driver circuit 600.

The guide portion 740 may be extended in the first direction DR1 from a point that is spaced (e.g., spaced apart) from one end of the cover member 700 in the first direction DR1 to a point spaced (e.g., spaced apart) from the opposite end of the cover member 700 in the first direction DR1, as shown in FIGS. 8 and 9 (e.g., also see FIGS. 2 and 5).

In addition, the guide portion 740 may be extended from one end of the cover member 700 in the first direction DR1 to the opposite end of the cover member 700 in the first direction DR1, as shown in FIGS. 10 and 11 (e.g., also see FIGS. 3 and 6).

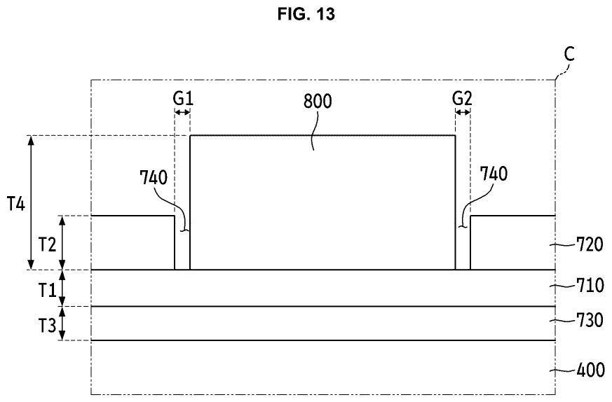

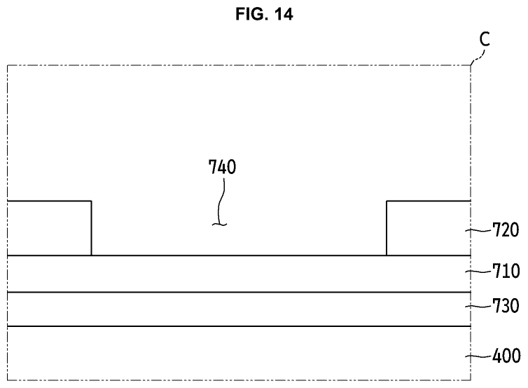

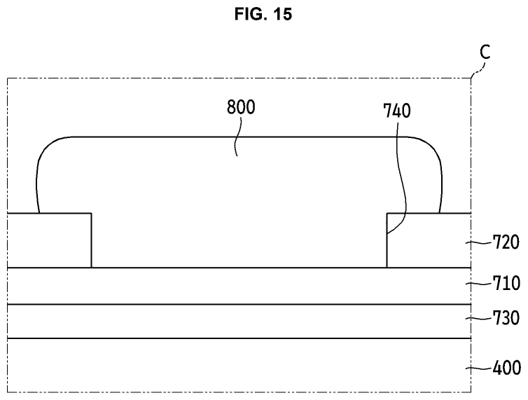

FIG. 13 is an enlarged view of a portion C of FIG. 7. FIG. 14 is a view showing the portion of FIG. 13 after the waterproof member 800 has been removed. FIG. 15 is a view showing the portion of FIG. 13 where waterproof glue is provided as the waterproof member 800.

Referring further to FIGS. 13-15, the waterproof member 800 may be disposed on the surface of the second cover sheet 720 such that at least a part of it is embedded in the second cover sheet 720. In one or more embodiments, the waterproof member 800 may be partially disposed inside the guide portion 740 and accordingly embedded in the second cover sheet 720.

The waterproof member 800 may be provided as a waterproof sheet. An adhesive layer may be disposed on the opposite surface of the waterproof member 800 so that the opposite surface of the waterproof member 800 may be adhered to the surface of the first cover sheet 710 exposed to the outside by the guide portion 740. Because the first cover sheet 710 may be provided as a metal sheet formed of a conductive material such as copper (Cu) and/or a polymer resin sheet such as polyethylene terephthalate and/or polyimide, the waterproof member 800 may be more easily adhered to the surface of the first cover sheet 710. The surface of the waterproof member 800 may be the upper surface of the waterproof member 800 in FIG. 13, and the opposite surface of the waterproof member 800 may be the lower side of the waterproof member 800 in FIG. 13.

The waterproof member 800 may be extended in the first direction DR1 and the second direction DR2. The extension length of the waterproof member 800 in the first direction DR1 may be larger than the extension length of the waterproof member 800 in the second direction DR2. In one or more embodiments, the waterproof member 800 may be a rectangular sheet having longer sides in the first direction DR1 and shorter sides in the second direction DR2.

The length of the waterproof member 800 in the first direction DR1 may be equal to the length of the guide portion 740 in the first direction DR1, and the length of the waterproof member 800 in the second direction DR2 may be smaller than the length of the guide portion 740 in the second direction DR2. In one or more embodiments, the both ends of the waterproof member 800 in the first direction DR1 may be in contact with the ends of the guide portion 740 in the first direction DR1, and the both ends of the waterproof member 800 in the second direction DR2 may be spaced (e.g., spaced apart) from the ends of the guide portion 740 in the second direction DR2. Gaps G1 and G2 may be formed between the both ends of the waterproof member 800 in the second direction DR2 and the ends of the guide portion 740 in the second direction DR2.

The thickness T4 of the waterproof member 800 may be larger than the thickness T1 of the first cover sheet 710 and the thickness T3 of the third cover sheet 730. In addition, the thickness T4 of the waterproof member 800 may be larger than the thickness T2 of the second cover sheet 720. Accordingly, even though a part of the waterproof member 800 is disposed inside the guide portion 740, the surface of the waterproof member 800 may be located higher than the surface of the second cover sheet 720 in FIG. 13. The thickness T4 of the waterproof member 800 may be equal to or less than twice the thickness T2 of the second cover sheet 720. In one or more embodiments, the thickness T2 of the second cover sheet 720 may be equal to approximately half the thickness T4 of the waterproof member 800.

The waterproof member 800 may be provided as a waterproof sheet as described above, but may also be provided as waterproof glue. When the waterproof member 800 is provided as waterproof glue, the waterproof member 800 may be applied to the inside of the guide portion 740 and stacked on the surface of the first cover sheet 710 exposed by the guide portion 740. The guide portion 740 may be filled with the waterproof member 800 applied into it. The waterproof member 800 may be applied onto the guide portion 740 to cover a part of the second cover sheet 720 around the guide portion 740. When the waterproof member 800 is provided as waterproof glue, the guide portion 740 may be fully filled with the waterproof member 800 so that no gap is formed between the guide portion 740 and the waterproof member 800.

Hereinafter, the operation and effects of a display device 10 according to one or more embodiments of the present disclosure will be described with reference to the accompanying drawings.

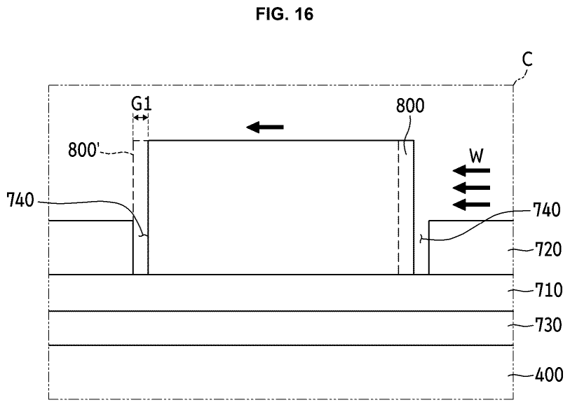

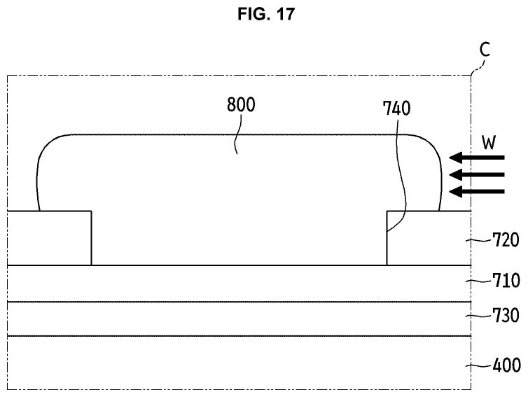

FIG. 16 is a view showing the portion of FIG. 13 when liquid is introduced from the outside. FIG. 17 is a view showing the portion of FIG. 15 when liquid is introduced from the outside.

Referring to FIG. 16, when liquid W is introduced into the inside of the display device 10 from the outside of the display device 10, the waterproof sheet, which is the waterproof member 800, blocks the liquid W, thereby preventing the display device 10 from being damaged by the liquid introduced from the outside. For example, when the driver circuit 600 is located on the left side of the portion of the display device 10 shown in FIG. 16 and the flexible film 500 is located on the right side of the portion of the display device 10 shown in FIG. 16, the liquid W introduced from the outside of the display device 10 may flow from the side where the flexible film 500 is located toward the side where the driver circuit 600 is located (e.g., see FIG. 7). In this manner, the liquid W introduced into the inside of the display device 10 is blocked by the waterproof member 800 and cannot flow into the driver circuit 600. Accordingly, the liquid W introduced from the outside of the display device 10 does not flow toward the driver circuit 600, and thus it is possible to prevent damage to the display device 10 by the liquid W introduced from the outside.

In addition, when the inflow pressure of the liquid W introduced from the outside of the display device 10 is high, the waterproof member 800 located at the correct position may be moved toward the left side of the portion of the display device 10 shown in FIG. 16. The waterproof member 800 moved toward the left side of the portion of the display device 10 shown in FIG. 16 may be blocked by the second cover sheet 720 and may be no longer moved toward the left side of the portion of the display device 10 shown in FIG. 16. Accordingly, even if the inflow pressure of the liquid W introduced from the outside of the display device 10 is high, the waterproof member 800 is only moved toward the left side of the portion of the display device 10 shown in FIG. 16 but still can prevent the liquid W from flowing toward the driver circuit 600. Accordingly, it is possible to prevent the display device 10 from being damaged by the liquid W introduced from the outside.

Referring to FIG. 17, when liquid W is introduced into the inside of the display device 10 from the outside of the display device 10, the waterproof glue, which is the waterproof member 800, blocks the liquid W, thereby preventing the display device 10 from being damaged by the liquid introduced from the outside. For example, when the driver circuit 600 is located on the left side of the portion of the display device 10 shown in FIG. 17 and the flexible film 500 is located on the right side of the portion of the display device 10 shown in FIG. 17, the liquid W introduced from the outside of the display device 10 may flow from the side where the flexible film 500 is located toward the side where the driver circuit 600 is located. In this manner, the liquid W introduced into the inside of the display device 10 is blocked by the waterproof member 800 and cannot flow into the driver circuit 600. Accordingly, the liquid W introduced from the outside of the display device 10 does not flow toward the driver circuit 600, and thus it is possible to prevent damage to the display device 10 by the liquid W introduced from the outside.

In addition, because the guide portion 740 is recessed in the thickness direction of the second cover sheet 720 from the surface of the second cover sheet 720, it is possible to prevent the waterproof member 800 from being disposed at a wrong position when the waterproof member 800 is disposed on the surface of the second cover sheet 720.

It should be understood, however, that the aspects and features of embodiments of the present disclosure are not restricted to the one set forth herein. The above and other aspects of the present disclosure will become more apparent to one of ordinary skill in the art to which the present disclosure pertains by referencing the claims, with equivalents thereof to be included therein.

What is claimed is:

1. A display device comprising:
a display panel;
a driver circuit on a surface of the display panel;
a cover member over the surface of the display panel and the driver circuit; and
a waterproof member on a surface of the cover member,
wherein at least a part of the waterproof member is embedded in the cover member.

2. The display device of claim 1, wherein the cover member further comprises a guide portion that is recessed from the surface of the cover member in a thickness direction of the cover member, and
wherein a part of the waterproof member is in the guide portion.

3. The display device of claim 2, wherein the cover member comprises: a first cover sheet on the surface of the display panel; and a second cover sheet on a surface of the first cover sheet.

4. The display device of claim 3, wherein the guide portion is recessed from a surface of the second cover sheet in a thickness direction of the second cover sheet.

5. The display device of claim 3, wherein the guide portion is an area where a part of the second cover sheet is removed so that a part of the surface of the first cover sheet is exposed to the outside, and
wherein the waterproof member is in contact with the surface of the first cover sheet that is exposed to the outside.

6. The display device of claim 2, wherein the guide portion is extended in a first direction and a second direction, and
wherein an extension length of the guide portion in the first direction is larger than an extension length of the guide portion in the second direction.

7. The display device of claim 6, wherein the guide portion is extended from one end of the cover member in the first direction to an opposite end in the first direction.

8. The display device of claim 6, wherein the waterproof member is in contact with an end of the guide portion in the first direction and is spaced from an end of the guide portion in the second direction.

9. The display device of claim 3, wherein the first cover sheet and the second cover sheet are formed of different materials.

10. The display device of claim 3, wherein the cover member further comprises a third cover sheet between the surface of the display panel and the first cover sheet.

11. A display device comprising:
a display panel;
a driver circuit on a surface of the display panel;
a first cover sheet over the surface of the display panel and the driver circuit;
a second cover sheet on a surface of the first cover sheet;
a guide portion formed by removing a part of the second cover sheet so that a part of the surface of the first cover sheet is exposed to an outside; and
a waterproof member in the guide portion and in contact with the surface of the first cover sheet exposed to the outside.

12. The display device of claim 11, wherein the guide portion is extended in a first direction and a second direction, and
wherein an extension length of the guide portion in the first direction is larger than an extension length of the guide portion in the second direction.

13. The display device of claim 12, wherein the guide portion is extended from one end of the first cover sheet in the first direction to an opposite end in the first direction.

14. The display device of claim 12, wherein the waterproof member is in contact with an end of the guide portion in the first direction and is spaced from an end of the guide portion in the second direction.

15. An electronic device comprising:
a display panel;
a driver circuit on a surface of the display panel;
a cover member over the surface of the display panel and the driver circuit; and
a waterproof member on a surface of the cover member,
wherein at least a part of the waterproof member is embedded in the cover member.

16. The electronic device of claim 15, wherein the cover member further comprises a guide portion that is recessed from the surface of the cover member in a thickness direction of the cover member, and
wherein a part of the waterproof member is inside the guide portion.

17. The electronic device of claim 16, wherein the cover member comprises:
a first cover sheet on the surface of the display panel; and
a second cover sheet on a surface of the first cover sheet.

18. The electronic device of claim 17, wherein the guide portion is recessed from a surface of the second cover sheet in a thickness direction of the second cover sheet.

19. The electronic device of claim 17, wherein the guide portion is an area where a part of the second cover sheet is removed so that a part of the surface of the first cover sheet is exposed to the outside, and
wherein the waterproof member is in contact with the surface of the first cover sheet that is exposed to the outside.

20. The electronic device of claim 16, wherein the guide portion is extended in a first direction and a second direction, and
wherein an extension length of the guide portion in the first direction is larger than an extension length of the guide portion in the second direction.
